(19) United States
(12) Patent Application Publication
(10) Pub. No.: US 2024/0145246 A1
(43) Pub. Date: May 2, 2024

(54) OXIDATION ENHANCED DOPING

(71) Applicant: Applied Materials, Inc., Santa Clara, CA (US)

(72) Inventors: Yi Yang, Fremont, CA (US); In Soo Jung, Campbell, CA (US); Sean S. Kang, San Ramon, CA (US); Srinivas D. Nemani, Saratoga, CA (US); Papo Chen, San Jose, CA (US); Ellie Y. Yieh, San Jose, CA (US)

(73) Assignee: Applied Materials, Inc., Santa Clara, CA (US)

(21) Appl. No.: 17/973,927

(22) Filed: Oct. 26, 2022

(51) Int. Cl. H01L 21/223; H01L 21/02; H01L 21/3065

(52) U.S. Cl. CPC H01L 21/223; H01L 21/02236; H01L 21/3065

(57) ABSTRACT

Embodiments of the present technology include semiconductor processing methods. The methods may include providing a silicon-containing precursor and a dopant precursor to a processing region of a semiconductor processing chamber. A substrate may be disposed within the semiconductor processing chamber. A silicon-containing material may be formed on the substrate. The methods may include contacting the silicon-containing material with the silicon-containing precursor and the dopant precursor. The methods may include forming a doped silicon-containing material on the silicon-containing material. The methods may include oxidizing the substrate. The oxidizing may form an oxidized doped silicon-containing material. The methods may include etching the oxidized doped silicon-containing material.

### TECHNICAL FIELD

The present technology relates to deposition and removal processes and chambers. More specifically, the present technology relates to systems and methods enhancing doping into a silicon material through oxidation.

### BACKGROUND

Integrated circuits are made possible by processes which produce intricately patterned material layers on substrate surfaces. Producing patterned material on a substrate requires controlled methods for forming and removing material. Material characteristics may affect how the device operates, and may also affect how the films are removed relative to one another. Deposition processes produce films having certain characteristics. Many films that are formed require additional processing to adjust or enhance the material characteristics of the film in order to provide suitable properties.

Thus, there is a need for improved systems and methods that can be used to produce high quality devices and structures. These and other needs are addressed by the present technology.

### SUMMARY

Embodiments of the present technology include semiconductor processing methods. The methods may include providing a silicon-containing precursor and a dopant precursor to a processing region of a semiconductor processing chamber. A substrate may be disposed within the semiconductor processing chamber. A silicon-containing material may be formed on the substrate. The methods may include contacting the silicon-containing material with the silicon-containing precursor and the dopant precursor. The methods may include forming a doped silicon-containing material on the silicon-containing material. The methods may include oxidizing the substrate. The oxidizing may form an oxidized doped silicon-containing material. The methods may include etching the oxidized doped silicon-containing material.

In some embodiments, a pressure within the semiconductor processing chamber may be maintained at less than or about 760 Torr. A temperature within the semiconductor processing chamber may maintained at less than or about 1200° C. The silicon-containing precursor may be or include silane (SiH₄), disilane (Si₂H₆), trisilane (Si₃H₈), tetrasilane (Si₄H₁₀), dichlorosilane (SiH₂Cl₂), or trichlorosilane (SiHCl₃). The dopant precursor may include phosphorous. the dopant precursor comprises boron. The methods may include providing an etchant precursor with the silicon-containing precursor and the dopant precursor. The etchant precursor may be or include an oxygen-containing precursor or a chlorine-containing precursor. Oxidizing the substrate may include contacting the substrate with an oxygen-containing precursor or treating the substrate with a laser. Oxidizing the substrate may increase a doping depth in the silicon-containing material to greater than or about 10 nm. The methods may include removing defective silicon-containing material formed on silicon-nitride material formed on the substrate.

Some embodiments of the present technology may encompass semiconductor processing methods. The methods may include providing a silicon-containing precursor and a dopant precursor to a processing region of a semiconductor processing chamber. A silicon-containing material may be deposited on a substrate disposed within the semiconductor processing chamber. The silicon-containing material may be a silicon channel of a 3D DRAM structure. The methods may include contacting the silicon-containing material with the silicon-containing precursor and the dopant precursor. The methods may include forming a doped silicon-containing material on the silicon-containing material. The methods may include oxidizing the substrate. The oxidizing may form an oxidized doped silicon-containing material.

In some embodiments, the doped silicon-containing material may be formed via chemical vapor deposition. The dopant precursor may be or include phosphine (PH₃), arsine (AsH₃), nitrogen, (N₂), ammonia (NH₃), germane (GeH₄), borane (BH₃), diborane (B₂H₆), trimethyl gallium (Ga(CH₃)₃), aluminum chloride (AlCl₃), trimethylaluminum (C₆H1₅Al), or methylsilane (CH₃SiH₃). The 3D DRAM structure further include a silicon-and-germanium-containing material deposited above and below the silicon-containing material and a silicon-and-nitrogen-containing material extending from the silicon-and-germanium-containing material. The silicon channel may extend between individual portions of the silicon-and-nitrogen-containing material. The silicon channel may be characterized by a depth of greater than or about 300 nm and a width of greater than or about 5 nm. The methods may include removing the oxidized doped silicon-containing material from the silicon-containing material. The methods may include removing silicon-containing byproduct from the silicon-and-nitrogen-containing material.

Some embodiments of the present technology may encompass semiconductor structures. The structures may include a silicon-containing substrate. The structures may include a silicon-and-germanium-containing material extending into recesses formed in the silicon-containing substrate. The structures may include a silicon-and-nitrogen-containing material extending from the silicon-and-germanium-containing material. The silicon-and-nitrogen-containing material may define a channel. The structures may include a doped silicon-containing material within the channel extending from the silicon-containing substrate.

In some embodiments, the silicon-containing substrate may be doped with a dopant from the doped silicon-containing material to a doping depth of greater than or about 10 nm. The doped silicon-containing material may be formed via chemical vapor deposition.

Such technology may provide numerous benefits over conventional processing methods. For example, an oxidation process after depositing doped silicon-containing material may drive the dopant further into the underlying material. This increased doping depth may lower resistivity and ohmic contact between the silicon channel and metal silicide. Additionally, the oxidation process may oxidize byproduct material formed on other materials of the structure. The subsequent removal or etch of the oxidized material may also remove byproduct material formed during the deposition of the doped silicon-containing material. These and other embodiments, along with many of their advantages and features, are described in more detail in conjunction with the below description and attached figures.

### BRIEF DESCRIPTION OF THE DRAWINGS

A further understanding of the nature and advantages of the disclosed technology may be realized by reference to the remaining portions of the specification and the drawings.

FIG. 1 shows a top plan view of an exemplary processing system according to some embodiments of the present technology.

FIG. 2 shows a schematic cross-sectional view of an exemplary plasma system according to some embodiments of the present technology.

FIG. 3 shows operations of an exemplary method of semiconductor processing according to some embodiments of the present technology.

FIGS. 4A-4D show cross-sectional views of a semiconductor structure according to some embodiments of the present technology.

Several of the figures are included as schematics. It is to be understood that the FIGS. are for illustrative purposes, and are not to be considered of scale unless specifically stated to be of scale. Additionally, as schematics, the figures are provided to aid comprehension and may not include all aspects or information compared to realistic representations, and may include exaggerated material for illustrative purposes.

In the appended figures, similar components and/or features may have the same reference label. Further, various components of the same type may be distinguished by following the reference label by a letter that distinguishes among the similar components. If only the first reference label is used in the specification, the description is applicable to any one of the similar components having the same first reference label irrespective of the letter.

### DETAILED DESCRIPTION

As 3D DRAM structures grow in size, the aspect ratios of silicon channels and other structures increase, sometimes dramatically. During 3D DRAM processing, silicon channels are formed when other materials, such as silicon nitride and silicon oxide form high aspect ratio features with silicon material, such as the substrate, forming a lower end of the features. In subsequent processing, source and drain regions are formed by doping underlying silicon-containing materials. Subsequent processing may form contacts on the source and drain regions.

Conventional doping of the underlying silicon-containing materials may be done by epitaxial growth of doped silicon. Depending on whether a source or drain is to be formed, the underlying silicon may be doped to be p-type or n-type silicon. Conventional doping includes epitaxial deposition of doped silicon on the underlying silicon-containing materials. A portion of the dopant in the silicon may travel into the underlying silicon-containing materials, thereby doping the underlying silicon-containing materials. However, as structures grow in size and demand increases for high quality structures, these conventional technologies may not provide adequate doping depths or concentrations. Additionally, conventional technologies deposit byproduct materials elsewhere on the structures that may frustrate subsequent processing, require intermediate processing to remove the byproduct material, or reduce final device function.

The present technology overcomes these issues by performing an oxidation process after depositing the doped silicon. The oxidation may drive additional dopant into the underlying silicon-containing material due to the bonding between the doped silicon and the oxidized silicon material. In addition to increased doping depths, the oxidation may drive increased amounts of dopant into the underlying silicon-containing materials, and may thereby increase dopant concentrations. The increased doping depths and increased dopant concentrations may lead to low resistivity and ohmic contact with the silicon channels and contacts, such as metal silicides. Additionally, the oxidation may oxidize byproduct material deposited elsewhere on the structure. A subsequent etch operation to remove the oxidized material proximate the doped silicon may also remove the oxidized byproduct material.

Although the remaining disclosure will routinely identify specific deposition and etch processes utilizing the disclosed technology, it will be readily understood that the systems and methods are equally applicable to other deposition and etch chambers, as well as processes as may occur in the described chambers. Accordingly, the technology should not be considered to be so limited as for use with these specific deposition processes or chambers alone. The disclosure will discuss one possible system and chamber that may be used to perform deposition processes according to embodiments of the present technology before additional details according to embodiments of the present technology are described.

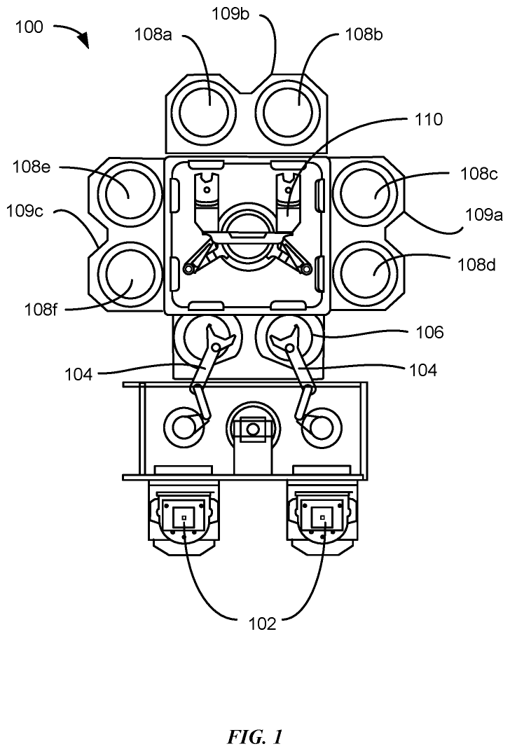

FIG. 1 shows a top plan view of one embodiment of a processing system 100 of deposition, etching, baking, and curing chambers according to embodiments. In the figure, a pair of front opening unified pods 102 supply substrates of a variety of sizes that are received by robotic arms 104 and placed into a low pressure holding area 106 before being placed into one of the substrate processing chambers 108a-f, positioned in tandem sections 109a-c. A second robotic arm 110 may be used to transport the substrate wafers from the holding area 106 to the substrate processing chambers 108a-f and back. Each substrate processing chamber 108a-f, can be outfitted to perform a number of substrate processing operations including formation of stacks of semiconductor materials described herein in addition to plasma-enhanced chemical vapor deposition, atomic layer deposition, physical vapor deposition, etch, pre-clean, degas, orientation, and other substrate processes including, annealing, ashing, etc.

The substrate processing chambers 108a-f may include one or more system components for depositing, annealing, curing and/or etching a hardmask layer on the substrate. In one configuration, two pairs of the processing chambers, e.g., 108c-d and 108e-f, may be used to deposit a hardmask layer on the substrate, and the third pair of processing chambers, e.g., 108a-b, may be used to etch the deposited hardmask (i.e., a hardmask opening operation). In another configuration, all three pairs of chambers, e.g., 108a-f, may be configured to deposit and etch hardmask layers on the substrate. Any one or more of the processes described may be carried out in chambers separated from the fabrication system shown in different embodiments. It will be appreciated that additional configurations of deposition, etching, annealing, and curing chambers for hardmask layers are contemplated by system 100.

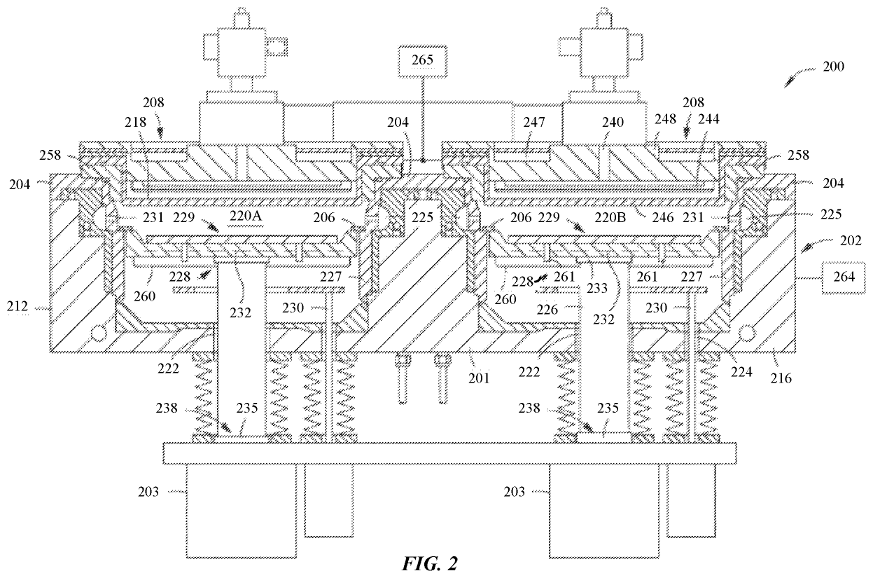

FIG. 2 shows a schematic cross-sectional view of an exemplary plasma system 200 according to some embodiments of the present technology. Plasma system 200 may illustrate a pair of processing chambers 108 that may be fitted in one or more of tandem sections 109 described above, and which may include lid stack components according to embodiments of the present technology, and as may be explained further below. The plasma system 200 generally may include a chamber body 202 having sidewalls 212, a bottom wall 216, and an interior sidewall 201 defining a pair of processing regions 220A and 220B. Each of the processing regions 220A-220B may be similarly configured, and may include identical components.

For example, processing region 220B, the components of which may also be included in processing region 220A, may include a pedestal 228 disposed in the processing region through a passage 222 formed in the bottom wall 216 in the plasma system 200. The pedestal 228 may provide a heater adapted to support a substrate 229 on an exposed surface of the pedestal, such as a body portion. The pedestal 228 may include heating elements 232, for example resistive heating elements, which may heat and control the substrate temperature at a desired process temperature. Pedestal 228 may also be heated by a remote heating element, such as a lamp assembly, or any other heating device.

The body of pedestal 228 may be coupled by a flange 233 to a stem 226. The stem 226 may electrically couple the pedestal 228 with a power outlet or power box 203. The power box 203 may include a drive system that controls the elevation and movement of the pedestal 228 within the processing region 220B. The stem 226 may also include electrical power interfaces to provide electrical power to the pedestal 228. The power box 203 may also include interfaces for electrical power and temperature indicators, such as a thermocouple interface. The stem 226 may include a base assembly 238 adapted to detachably couple with the power box 203. A circumferential ring 235 is shown above the power box 203. In some embodiments, the circumferential ring 235 may be a shoulder adapted as a mechanical stop or land configured to provide a mechanical interface between the base assembly 238 and the upper surface of the power box 203.

A rod 230 may be included through a passage 224 formed in the bottom wall 216 of the processing region 220B and may be utilized to position substrate lift pins 261 disposed through the body of pedestal 228. The substrate lift pins 261 may selectively space the substrate 229 from the pedestal to facilitate exchange of the substrate 229 with a robot utilized for transferring the substrate 229 into and out of the processing region 220B through a substrate transfer port 260.

A chamber lid 204 may be coupled with a top portion of the chamber body 202. The lid 204 may accommodate one or more precursor distribution systems 208 coupled thereto. The precursor distribution system 208 may include a precursor inlet passage 240 which may deliver reactant and cleaning precursors through a dual-channel showerhead 218 into the processing region 220B. The dual-channel showerhead 218 may include an annular base plate 248 having a blocker plate 244 disposed intermediate to a faceplate 246. A radio frequency (“RF”) source 265 may be coupled with the dual-channel showerhead 218, which may power the dual-channel showerhead 218 to facilitate generating a plasma region between the faceplate 246 of the dual-channel showerhead 218 and the pedestal 228. The dual-channel showerhead 218 and/or faceplate 246 may include one or more openings to permit the flow of precursors from the precursor distribution system 208 to the processing regions 220A and/or 220B. In some embodiments, the openings may include at least one of straight-shaped openings and conical-shaped openings. In some embodiments, the RF source may be coupled with other portions of the chamber body 202, such as the pedestal 228, to facilitate plasma generation. A dielectric isolator 258 may be disposed between the lid 204 and the dual-channel showerhead 218 to prevent conducting RF power to the lid 204. A shadow ring 206 may be disposed on the periphery of the pedestal 228 that engages the pedestal 228.

An optional cooling channel 247 may be formed in the annular base plate 248 of the precursor distribution system 208 to cool the annular base plate 248 during operation. A heat transfer fluid, such as water, ethylene glycol, a gas, or the like, may be circulated through the cooling channel 247 such that the base plate 248 may be maintained at a predefined temperature. A liner assembly 227 may be disposed within the processing region 220B in close proximity to the sidewalls 201, 212 of the chamber body 202 to prevent exposure of the sidewalls 201, 212 to the processing environment within the processing region 220B. The liner assembly 227 may include a circumferential pumping cavity 225, which may be coupled to a pumping system 264 configured to exhaust gases and byproducts from the processing region 220B and control the pressure within the processing region 220B. A plurality of exhaust ports 231 may be formed on the liner assembly 227. The exhaust ports 231 may be configured to allow the flow of gases from the processing region 220B to the circumferential pumping cavity 225 in a manner that promotes processing within the system 200.

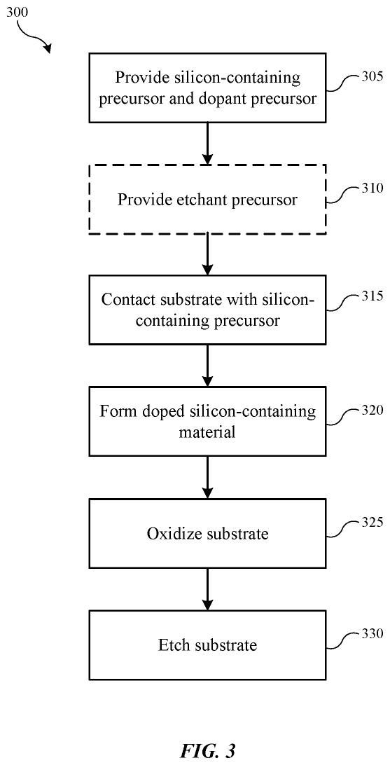

As noted above, the present technology may form a doped silicon-containing material that, after oxidation, may drive the dopant into the underlying material. Turning to FIG. 3 is shown exemplary operations in a method 300 for forming a semiconductor structure according to embodiments of the present technology. Method 300 may include one or more operations prior to the initiation of the method, including front-end processing, deposition, etching, polishing, cleaning, or any other operations that may be performed prior to the described operations. For example, the method may begin after a number of layers have been deposited, such as for producing 3D DRAM structures. However, as explained above, it is to be understood that the figures illustrate just one exemplary process in which processes according to embodiments of the present technology may be employed, and the description is not intended to limit the technology to this process alone. Some or all of the operations may be performed in chambers or system tools as previously described, or may be performed in different chambers on the same system tool, which may include the chamber in which the operations of method 300 may be performed.

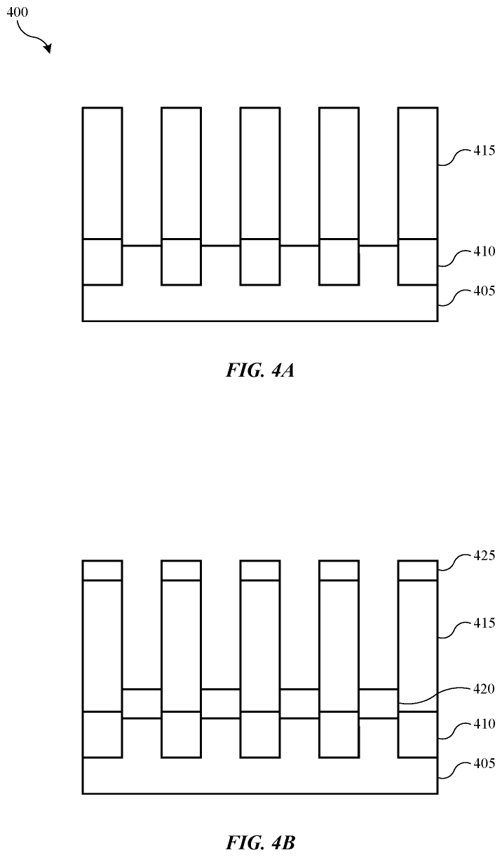

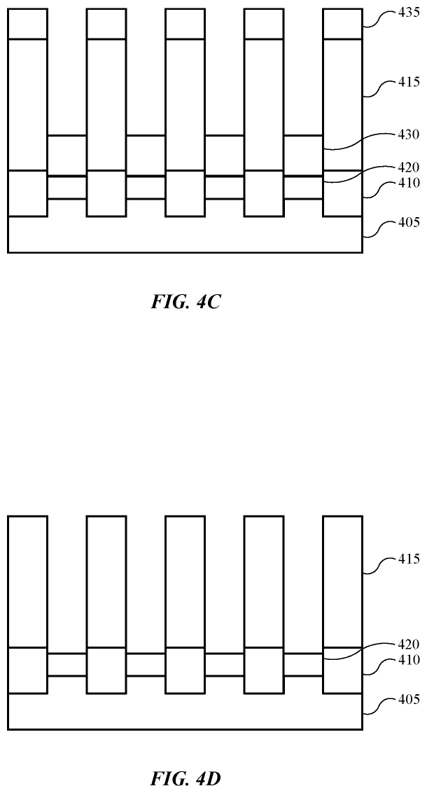

Method 300 may include a number of optional operations as illustrated, which may or may not be specifically associated with some embodiments of methods according to the present technology. For example, many of the operations are described in order to provide a broader scope of the structural formation, but are not critical to the technology, or may be performed by alternative methodology as will be discussed further below. Method 300 describes operations shown schematically in FIGS. 4A-4D, the illustrations of which will be described in conjunction with the operations of method 300. It is to be understood that FIGS. 4A-4D illustrate only partial schematic views, and a substrate may contain any number of structural sections having aspects as illustrated in the figures, as well as alternative structural aspects that may still benefit from operations of the present technology.

Method 300 may or may not involve optional operations to develop the semiconductor structure to a particular fabrication operation. It is to be understood that method 300 may be performed on any number of semiconductor structures or substrates 405, as illustrated in FIG. 4A, including exemplary structures on which oxidation enhanced doping may be formed. As illustrated in FIG. 4A substrate 405 may have a number of layers of material deposited overlying the substrate. Substrate 405 may be any number of materials, such as a base wafer or substrate made of silicon or silicon-containing materials, germanium, other substrate materials, as well as one or more materials that may be formed overlying the substrate during semiconductor processing.

Structure 400 may illustrate a partial view of a stack of alternating layers of materials, which in some embodiments may be used in 3D DRAM memory formation. As shown in FIG. 4A, structure 400 may include a material extending into recesses formed in the substrate 405. The material may be a silicon-and-germanium-containing material 410. A silicon-and-nitrogen-containing material 415 may extend from the silicon-and-germanium-containing material 410, and may define silicon channels in the structure, such as a silicon channel in a 3D DRAM structure. That is, the silicon channel may extend between individual portions of the silicon-and-nitrogen-containing material 415. The silicon channel may be characterized by a depth of greater than or about 300 nm, such as greater than or about 400 nm, greater than or about 500 nm, greater than or about 600 nm, greater than or about 700 nm, or more. The silicon channel may be characterized by a width or critical dimension of greater than or about 5 nm, such as greater than or about 25 nm, greater than or about 50 nm, greater than or about 75 nm, greater than or about 100 nm, or more.

At operation 305, method 300 may include providing a silicon-containing precursor and a dopant precursor to a processing region of a semiconductor processing chamber, such as processing region of the chamber in plasma system 200. Substrate 405 and the layers previously discussed may be present in the substrate processing region of the semiconductor processing chamber as the deposition precursors flow into the chamber. Silicon-containing precursors that may be used in operation 305 may be or include any number of silicon-containing precursors. For example, any silicon-containing precursor for depositing a silicon-containing material, such as a doped silicon-containing material, may be used. As non-limiting examples, in embodiments of the present technology the silicon-containing precursor may be or include silane (SiH₄), disilane (Si₂H₆), trisilane (Si₃H₈), tetrasilane (Si₄H₁₀), dichlorosilane (SiH₂Cl₂), or trichlorosilane (SiHCl₃). A flow rate for the silicon-containing precursor may be greater than or about 50 sccm, greater than or about 100 sccm, greater than or about 250 sccm, greater than or about 500 sccm, greater than or about 1000 sccm, greater than or about 2500 sccm, greater than or about 5000 sccm, greater than or about 10000 sccm, or more.

The dopant precursors that may be used in operation 305 may be or include any number of dopant precursors. For example, any dopant precursor for depositing a doped silicon-containing material may be used. As non-limiting examples, in embodiments of the present technology the dopant precursor may include phosphorous or boron, such as for forming doped source regions or drain regions. For example, the dopant precursor may be or include phosphine (PH₃), arsine (AsH₃), nitrogen, (N₂), ammonia (NH₃), germane (GeH₄), borane (BH₃), diborane (B₂H₆), trimethyl gallium (Ga(CH₃)₃), aluminum chloride (AlCl₃), trimethylaluminum (C₆H1₅Al), or methylsilane (CH₃SiH₃). A flow rate for the dopant precursor may be greater than or about 50 sccm, greater than or about 100 sccm, greater than or about 250 sccm, greater than or about 500 sccm, greater than or about 1000 sccm, greater than or about 2500 sccm, greater than or about 5000 sccm, greater than or about 10000 sccm, or more. A flow rate of the dopant precursor may depend on the target doping concentration, as well as other process conditions such as temperature and pressure. However, compared to conventional epitaxial growth processes, a lower dopant precursor flow rate may be required due to the effects of the subsequent oxidation to be described herein.

At optional operation 310, method 300 may include providing an etchant precursor with the silicon-containing precursor and the dopant precursor. The etchant precursor may maintain selective deposition of material. As previously discussed, structure 400 includes multiple materials and providing an etchant precursor may reduce and/or remove material undesirably deposited on other materials in the structure 400. For example, any etchant precursor for reducing and/or removing material from silicon-and-nitrogen-containing material 415, as one non-limiting example, may be provided with the silicon-containing precursor and the dopant precursor. As non-limiting examples, in embodiments of the present technology the etchant precursor may include an oxygen-containing precursor or a chlorine-containing precursor. For example, the etchant precursor may be or include molecular oxygen (O₂), hydrogen chloride (HCl), or diatomic chlorine (Cl₂). However, in some embodiments, the etchant precursor may not include an oxygen-containing precursor in order to maintain the semiconductor processing chamber oxygen-free. By maintaining the semiconductor processing chamber oxygen-free, the silicon-containing material to be deposited may be free of oxygen, which may increase the driving of the dopant into the underlying material as discussed herein.

A carrier gas may be combined with the silicon-containing precursor and/or the dopant precursor flowing into the substrate processing region of the substrate processing chamber. In embodiments, the carrier gas may be one or more of helium, argon, molecular nitrogen (N₂), and molecular hydrogen (H₂), among other carrier gases. The carrier gas may benefit the mechanical properties of the film. Additionally, the carrier gas may also make it easier to strike a plasma.

Once the silicon-containing precursor and the dopant precursor are provided to the processing region, method 300 may include forming a plasma of the silicon-containing precursor and the dopant precursor within the processing region. The plasma of the silicon-containing precursor and the dopant precursor may be generated at any plasma power suitable for depositing doped silicon-containing material. Generating a plasma of the silicon-containing precursor and the dopant precursor may increase a rate of deposition as well as promote interaction between the precursors thereby increasing a boron concentration or phosphorous in the deposited material.

At operation 315, method 300 may include contacting the substrate 405, which may be a silicon-containing material, with the silicon-containing precursor and the dopant precursor. As shown in FIG. 4B, at operation 320, method 300 may include forming a doped silicon-containing material 420. The doped silicon-containing material 420 may be formed on the silicon-containing material of the substrate 405. The doped silicon-containing material may formed via chemical vapor deposition (CVD), which may include atomic layer epitaxy (ALE). Chemical vapor deposition includes the use of many techniques, such as plasma-assisted CVD (PACVD), plasma-enhanced CVD (PECVD), atomic layer CVD (ALCVD), organometallic or metalorganic CVD (OMCVD or MOCVD), laser-assisted CVD (LA-CVD), ultraviolet CVD (UV-CVD), hot-wire CVD (HWCVD), reduced-pressure CVD (RP-CVD), and ultra-high vacuum CVD (UHV-CVD).

A thickness of the dope silicon-containing material 420 may impact the doping depth of the dopant into the underlying material, such as the carbon-containing material of the substrate 405. At greater thicknesses of the doped silicon-containing material 420, the dopant may be driven further into the underlying material to a greater doping depth and/or the concentration of dopant in the underlying material may increase. In embodiments, a thickness of the doped silicon-containing material 420 may be greater than or about 5 nm, such as greater than or about nm, greater than or about 15 nm, greater than or about 20 nm, greater than or about 25 nm, greater than or about 30 nm, greater than or about 35 nm, greater than or about 40 nm, greater than or about 45 nm, greater than or about 50 nm, or more. While greater thicknesses are contemplated, a thickness less than or about 50 nm or less than or about 25 nm may be sufficient.

While forming the doped silicon-containing material 420, byproduct material 425 may deposit on other materials in the structure 400, such as the silicon-and-nitrogen-containing material 415. As previously discussed, an etchant precursor may be provided with the silicon-containing precursor and the dopant precursor, but some deposition of material may nonetheless occur on surrounding materials. The byproduct material 425 or defect material may include polycrystalline or amorphous silicon-containing material.

The deposition temperature of the materials may impact the deposition on the exposed materials. Accordingly, in some embodiments, forming the doped silicon-containing materials may performed at a temperature of less than or about 1200° C., and the process may be performed at a temperature of less than or about 1100° C., less than or about 1000° C., less than or about 900° C., less than or about 800° C., less than or about 700° C., less than or about 600° C., less than or about 500° C., less than or about 400° C., less than or about 300° C., less than or about 200° C., or less.

Deposition pressure may also impact the deposition on the exposed materials. For example, higher pressures may increase directionality of the silicon-containing precursor and the dopant precursor. Accordingly, in some embodiments, forming the carbon-containing materials may include specific materials delivered at a pressure of less than or about 760 Torr, and may be less than or about 700 Torr, less than or about 600 Torr, less than or about 500 Torr, less than or about 400 Torr, less than or about 300 Torr, less than or about 200 Torr, less than or about 100 Torr, less than or about 50 Torr, less than or about 10 Torr, less than or about 5 Torr, less than or about 1 Torr, less than or about 500 mTorr, less than or about 250 mTorr, less than or about 100 mTorr, less than or about 1 mTorr, less than or about 0.1 mTorr, or less. At high pressures, such as pressures greater than 760 Torr, selectivity may decrease. At lower pressures, such as pressures below 0.1 mTorr, doping concentration may reduce. Accordingly, a pressure may be maintained between about 0.1 mTorr and about 760 Torr, or any other range encompassed between these values.

As shown in FIG. 4C, at operation 325, method 300 may include oxidizing the substrate 405. In embodiments, method 300 may include transferring the substrate 405 from a first chamber to a second chamber prior to oxidizing the substrate 405. However, it is contemplated that the substrate 405 may be maintained in one chamber for both the deposition and oxidation. During the oxidation process at operation 325, the silicon-containing precursor and/or the dopant precursor may continue to be provided. The continuous provision of the silicon-containing precursor and/or the dopant precursor may allow a silicon-and-oxygen-containing material 430 to be formed over the doped silicon-containing material 420 previously deposited. Alternatively, if the silicon-containing precursor is not provided, the silicon-and-oxygen-containing material 430 may form via interaction with the underlying doped silicon-containing material 420. Oxidizing the structure 400, including the substrate 405, may drive dopant material, such as phosphorous or boron, into the material underlying the doped silicon-containing material 420, such as the silicon-containing material of the substrate 405. The formation of silicon-and-oxygen-containing material 430 may result in bonding with the doped silicon-containing material 420. This bonding may Si—O bonds which may have a lower activation energy than bonds between silicon and the dopant. The lower activation energy may allow the dopant, such as phosphorous or boron, to release and be driven into the underlying material. While oxidizing the substrate 405, the byproduct material 425 may also be oxidized to form oxidized byproduct material 435.

Oxidizing the substrate 405 at operation 325 may include contacting the substrate 405 with an oxygen-containing precursor or treating the substrate 405 with a laser. In embodiments where oxidizing the substrate 405 includes contacting the substrate 405 with an oxygen-containing precursor, the oxygen-containing precursor may be any oxygen-containing precursor operable to form oxidized material. For example, the oxygen-containing precursor may be steam or water (H₂O), molecular oxygen (O₂), or any other oxygen-containing precursor used in semiconductor processing. The oxygen-containing precursor, which may or may not be provided with a silicon-containing precursor, may form a silicon-and-oxygen-containing material 430 over the doped silicon-containing material 420. In embodiments where oxidizing the substrate 405 includes treating the substrate 405 with a laser, ultraviolet (UV) pulsed laser excitation in an oxygen environment may form the silicon-and-oxygen-containing material 430 over the doped silicon-containing material 420. Either contacting the substrate 405 with the oxygen-containing precursor or treating the substrate 405 with the laser may form the silicon-and-oxygen-containing material 430 over the doped silicon-containing material 420. As previously discussed, the formation and bonding of silicon-and-oxygen-containing material 430 over the doped silicon-containing material 420 may drive the dopant into the underlying material.

Similar to the doped silicon-containing material 420, a thickness of the silicon-and-oxygen-containing material 430 may impact the doping depth of the dopant into the underlying material, such as the carbon-containing material of the substrate 405. At greater thicknesses of the silicon-and-oxygen-containing material 430, the dopant may be driven further into the underlying material to a greater doping depth and/or the concentration of dopant in the underlying material may increase. In embodiments, a thickness of the silicon-and-oxygen-containing material 430 may be greater than or about 10 nm, such as greater than or about 20 nm, greater than or about 30 nm, greater than or about 40 nm, greater than or about 50 nm, greater than or about 60 nm, greater than or about 70 nm, greater than or about 80 nm, greater than or about 90 nm, greater than or about 100 nm, or more. While greater thicknesses are contemplated, a thickness less than or about 50 nm or 20 nm may be sufficient. In embodiments, the thickness of the silicon-and-oxygen-containing material 430 may be at least double the thickness of the doped silicon-containing material 420, which may allow for the silicon-and-oxygen-containing material 430 and resultant bonding to drive dopant material into the underling material.

The oxidation temperature of the materials may impact the dopant incorporation on the underlying materials, such as the substrate 405. Accordingly, in some embodiments, oxidizing the substrate 405 may performed at a temperature of greater than or about 500° C., and the oxidation process may be performed at a temperature of greater than or about 550° C., greater than or about 600° C., greater than or about 650° C., greater than or about 700° C., greater than or about 750° C., greater than or about 800° C., greater than or about 850° C., greater than or about 900° C., greater than or about 950° C., greater than or about 1000° C., or more. In embodiments, oxidizing the substrate 405 may performed at a temperature of between about 650° C. and about 750° C. At greater oxidation temperatures, it may be easier to oxidize the structure 400 and form the silicon-and-oxygen-containing material 430. However, thermal budgets may limit the temperature at which the oxidation process may be performed. Accordingly, in some embodiments, oxidizing the substrate 405 may performed at a temperature of greater than or about 1000° C., and the oxidation process may be performed at a temperature of greater than or about 950° C., greater than or about 900° C., greater than or about 850° C., greater than or about 800° C., greater than or about 750° C., greater than or about 700° C., greater than or about 650° C., greater than or about 600° C., greater than or about 550° C., greater than or about 500° C., or less. However, lower oxidation temperatures may slow the formation of the silicon-and-oxygen-containing material 430, which may also limit the driving of the dopant into the underlying material.

Oxidation pressure may also impact the dopant incorporation on the underlying materials, such as the substrate 405. The oxidation pressure may be maintained at greater than or about 1 Torr, and may be maintained at greater than or about 5 Torr, greater than or about 10 Torr, greater than or about 50 Torr, greater than or about 100 Torr, greater than or about 200 Torr, greater than or about 300 Torr, greater than or about 400 Torr, greater than or about 500 Torr, greater than or about 600 Torr, greater than or about 700 Torr, greater than or about 760 Torr, or more. At greater pressures, which may indicate a higher oxidant flow rate, oxidation rate may increase. An increased oxidation rate may drive the dopant further into the underlying material, increasing doping depth and/or concentration.

The oxidation at operation 325 may continue for an amount of time sufficient to form the silicon-and-oxygen-containing material to a desired thickness. In embodiments, the oxidation may continue for greater than or about 1 minute, such as greater than or about 5 minutes, greater than or about 10 minutes, greater than or about 15 minutes, greater than or about 20 minutes, greater than or about 25 minutes, greater than or about 30 minutes, greater than or about 35 minutes, greater than or about 40 minutes, greater than or about 45 minutes, greater than or about 50 minutes, greater than or about 55 minutes, greater than or about 60 minutes, or more. However, at longer durations, increased oxidation durations may oxidize the substrate 405 to a high degree or damage the structure 400 due to thermal budgets. Accordingly, in some embodiments, the oxidation may continue for less than or about 30 minutes, such as less than or about 25 minutes, less than or about 20 minutes, less than or about 15 minutes, less than or about 10 minutes, or less.

After the oxidation process, a doping depth in the silicon-containing material of the substrate 405 may be greater than or about 10 nm, and may be greater than or about 15 nm, greater than or about 20 nm, greater than or about 25 nm, greater than or about 30 nm, greater than or about 35 nm, greater than or about 40 nm, greater than or about 45 nm, greater than or about 50 nm, greater than 55 nm, greater than 60 nm, greater than 65 nm, greater than 70 nm, greater than 75 nm, greater than 80 nm, or more. Compared to conventional technologies where a post-deposition oxidation step is not performed, the doping depth and concentration provided by the present embodiments may be greatly increased. In conventional technologies, the doping depth may be limited to less than 10 nm or less. This increased doping depth and concentration may result in low resistivity and ohmic contact with the silicon channel and a subsequently formed metal silicide, such as a contact in the 3D DRAM structure.

As shown in FIG. 4D, at operation 330, method 300 may include etching the silicon-and-oxygen-containing material 430. In embodiments, method 300 may include transferring the substrate 405 from a first chamber to a second chamber prior to etching. However, it is contemplated that the substrate 405 may be maintained in one chamber for both the oxidation and etching. The etching operation may include any wet etch or dry etch process. For example, a wet etch process using a fluorine-containing precursor, such as dilute hydrofluoric acid (DHF), may be performed to etch and remove the oxidized doped silicon-containing material 420. The underlying doped silicon-containing material 420 may serve as an etch stop and may remain after operation 330. In embodiments, a dry etch operation may be performed using a fluorine-containing precursor, such as difluoromethane (CH₂F₂) or any other fluorine-containing precursor. A fluorine-containing precursor used in a dry etch operation may include a fluorocarbon with a high carbon to fluorine ratio, such as greater than 1:2, to maximize etch selectivity between the silicon-and-oxygen-containing material 430 and other material in the structure 400, such as the silicon-and-nitrogen-containing material 415. While etching the oxidized doped silicon-containing material 420, the oxidized byproduct material 435 may also be removed. For example, the carbon to fluorine ratio may maintain an etch selectivity of SiO₂:SiNₓ of greater than 5:1 or greater than 10:1.

Compared to conventional technologies, the present embodiments may successfully drive dopant further into the underlying material. Conventional technologies also create unwanted byproduct material on other materials during deposition of the doped material to be driven into the underlying material. The present embodiments, in addition to driving dopant further into the underlying material through an oxidation step, may oxidize unwanted byproduct material. During subsequent etching or removal operations, this oxidized unwanted byproduct material may also be removed, creating a cleaner and more desirable structure.

In the preceding description, for the purposes of explanation, numerous details have been set forth in order to provide an understanding of various embodiments of the present technology. It will be apparent to one skilled in the art, however, that certain embodiments may be practiced without some of these details, or with additional details.

Having disclosed several embodiments, it will be recognized by those of skill in the art that various modifications, alternative constructions, and equivalents may be used without departing from the spirit of the embodiments. Additionally, a number of well-known processes and elements have not been described in order to avoid unnecessarily obscuring the present technology. Accordingly, the above description should not be taken as limiting the scope of the technology.

Where a range of values is provided, it is understood that each intervening value, to the smallest fraction of the unit of the lower limit, unless the context clearly dictates otherwise, between the upper and lower limits of that range is also specifically disclosed. Any narrower range between any stated values or unstated intervening values in a stated range and any other stated or intervening value in that stated range is encompassed. The upper and lower limits of those smaller ranges may independently be included or excluded in the range, and each range where either, neither, or both limits are included in the smaller ranges is also encompassed within the technology, subject to any specifically excluded limit in the stated range. Where the stated range includes one or both of the limits, ranges excluding either or both of those included limits are also included.

As used herein and in the appended claims, the singular forms “a”, “an”, and “the” include plural references unless the context clearly dictates otherwise. Thus, for example, reference to “a material” includes a plurality of such materials, and reference to “the precursor” includes reference to one or more precursors and equivalents thereof known to those skilled in the art, and so forth.

Also, the words “comprise(s)”, “comprising”, “contain(s)”, “containing”, “include(s)”, and “including”, when used in this specification and in the following claims, are intended to specify the presence of stated features, integers, components, or operations, but they do not preclude the presence or addition of one or more other features, integers, components, operations, acts, or groups.

1. A semiconductor processing method comprising:
providing a silicon-containing precursor and a dopant precursor to a processing region of a semiconductor processing chamber, wherein a substrate is disposed within the semiconductor processing chamber, and wherein a silicon-containing material is formed on the substrate;
contacting the silicon-containing material with the silicon-containing precursor and the dopant precursor;
forming a doped silicon-containing material on the silicon-containing material;
oxidizing the substrate, wherein the oxidizing forms an oxidized doped silicon-containing material; and
etching the oxidized doped silicon-containing material.

2. The semiconductor processing method of claim 1, wherein a pressure within the semiconductor processing chamber is maintained at less than or about 760 Torr.

3. The semiconductor processing method of claim 1, wherein a temperature within the semiconductor processing chamber is maintained at less than or about 1200° C.

4. The semiconductor processing method of claim 1, wherein the silicon-containing precursor comprises silane (SiH₄), disilane (Si₂H₆), trisilane (Si₃H₈), tetrasilane (Si₄H₁₀), dichlorosilane (SiH₂Cl₂), or trichlorosilane (SiHCl₃).

5. The semiconductor processing method of claim 1, wherein the dopant precursor comprises phosphorous.

6. The semiconductor processing method of claim 1, wherein the dopant precursor comprises boron.

7. The semiconductor processing method of claim 1, further comprising:
providing an etchant precursor with the silicon-containing precursor and the dopant precursor, wherein the etchant precursor comprises an oxygen-containing precursor or a chlorine-containing precursor.

8. The semiconductor processing method of claim 1, wherein oxidizing the substrate comprises contacting the substrate with an oxygen-containing precursor or treating the substrate with a laser.

9. The semiconductor processing method of claim 1, wherein oxidizing the substrate increases a doping depth in the silicon-containing material to greater than or about 10 nm.

10. The semiconductor processing method claim 1, further comprising:
removing defective silicon-containing material formed on silicon-nitride material formed on the substrate.

11. A semiconductor processing method comprising:
providing a silicon-containing precursor and a dopant precursor to a processing region of a semiconductor processing chamber, wherein a silicon-containing material is deposited on a substrate disposed within the semiconductor processing chamber, and wherein the silicon-containing material comprises a silicon channel of a 3D DRAM structure;
contacting the silicon-containing material with the silicon-containing precursor and the dopant precursor;
forming a doped silicon-containing material on the silicon-containing material; and
oxidizing the substrate, wherein the oxidizing forms an oxidized doped silicon-containing material.

12. The semiconductor processing method of claim 11, wherein the doped silicon-containing material is formed via chemical vapor deposition.

13. The semiconductor processing method of claim 11, wherein the dopant precursor comprises phosphine (PH₃), arsine (AsH₃), nitrogen, (N₂), ammonia (NH₃), germane (GeH₄), borane (BH₃), diborane (B₂H₆), trimethyl gallium (Ga(CH₃)₃), aluminum chloride (AlCl₃), trimethylaluminum (C₆H1₅Al), or methylsilane (CH₃SiH₃).

14. The semiconductor processing method of claim 11, wherein the 3D DRAM structure further comprises:
a silicon-and-germanium-containing material deposited above and below the silicon-containing material; and
a silicon-and-nitrogen-containing material extending from the silicon-and-germanium-containing material.

15. The semiconductor processing method of claim 14, wherein:
the silicon channel extends between individual portions of the silicon-and-nitrogen-containing material; and
the silicon channel is characterized by a depth of greater than or about 300 nm and a width of greater than or about 5 nm.

16. The semiconductor processing method of claim 11, further comprising:
removing the oxidized doped silicon-containing material from the silicon-containing material.

17. The semiconductor processing method of claim 14, further comprising:
removing silicon-containing byproduct from the silicon-and-nitrogen-containing material.

18. A semiconductor structure comprising:
a silicon-containing substrate;
a silicon-and-germanium-containing material extending into recesses formed in the silicon-containing substrate;
a silicon-and-nitrogen-containing material extending from the silicon-and-germanium-containing material, wherein the silicon-and-nitrogen-containing material defines a channel; and
a doped silicon-containing material within the channel extending from the silicon-containing substrate.

19. The semiconductor structure of claim 18, wherein the silicon-containing substrate is doped with a dopant from the doped silicon-containing material to a doping depth of greater than or about 10 nm.

20. The semiconductor structure of claim 18, wherein the doped silicon-containing material is formed via chemical vapor deposition.
